(19) United States
(12) Patent Application Publication
(10) Pub. No.: US 2024/0321799 A1
(43) Pub. Date: Sep. 26, 2024

(54) SEMICONDUCTOR PACKAGE

(71) Applicant: SAMSUNG ELECTRONICS CO., LTD., SUWON-SI (KR)

(72) Inventor: Kiwon Baek, Suwon-si (KR)

(21) Appl. No.: 18/612,648

(22) Filed: Mar. 21, 2024

(30) Foreign Application Priority Data
Mar. 24, 2023 (KR) 10-2023-0039224
May 11, 2023 (KR) 10-2023-0061349

(51) Int. Cl. H01L 23/00

(52) U.S. Cl. CPC H01L 24/14; H01L 24/13; H01L 24/16; H01L 2224/13013; H01L 2224/13014; H01L 2224/1403; H01L 2224/14051; H01L 2224/14177; H01L 2224/16227; H01L 2924/10252; H01L 2924/10253; H01L 2924/10272; H01L 2924/10329; H01L 2924/10333; H01L 2924/10335

(57) ABSTRACT

Provided is a semiconductor package including a first substrate, a first pattern and a second pattern disposed on the first substrate, a semiconductor chip disposed on the first substrate and including a metal layer, a circuit structure disposed on the metal layer of the semiconductor chip, and a plurality of first bumps disposed between the first substrate and the semiconductor chip and electrically connected to the first pattern, wherein the first pattern includes a ground pattern or a power pattern, the first substrate includes a first region overlapping the circuit structure in a vertical direction, the plurality of first bumps are disposed adjacent to the first region on a top surface of the first substrate, and a first bump of the plurality of first bumps has an elongated shape substantially parallel to an adjacent side of the first region.

### CROSS-REFERENCE TO RELATED APPLICATIONS

This application is based on and claims priority under 35 U.S.C. § 119 to Korean Patent Application No. 10-2023-0039224, filed on Mar. 24, 2023, in the Korean Intellectual Property Office, and Korean Patent Application No. 10-2023-0061349, filed on May 11, 2023, in the Korean Intellectual Property Office, the disclosures of which are incorporated by reference herein in their entirety.

### BACKGROUND

### 1. Technical Field

The disclosure relates to a semiconductor package, and more particularly, to a semiconductor package including a circuit structure disposed on a metal layer.

### 2. Discussion of Related Art

To improve the performance of electronic devices and semiconductor devices thereof, an operating speed and a storage capacity of the semiconductor devices may be increased and, at the same time, semiconductor packages including the semiconductor devices may be made thin and light. As the operating speed and storage capacity of the semiconductor devices are developed, a structural reliability of the semiconductor devices may be impacted.

### SUMMARY

The disclosure provides a semiconductor package with improved reliability, which may reduce or prevent noise coupling of a circuit structure disposed on a metal layer.

In addition, aspects of the disclosure are not limited to those mentioned herein, and other aspects may be clearly understood by one of ordinary skill in the art from the following descriptions.

According to an aspect of the disclosure, there is provided a semiconductor package including a first substrate, a first pattern and a second pattern disposed on the first substrate, a semiconductor chip disposed on the first substrate and including a metal layer, a circuit structure disposed on the metal layer of the semiconductor chip, and a plurality of first bumps disposed between the first substrate and the semiconductor chip and electrically connected to the first pattern, wherein the first pattern includes a ground pattern or a power pattern, the first substrate includes a first region overlapping the circuit structure in a vertical direction, the plurality of first bumps are disposed adjacent to the first region on a top surface of the first substrate, and a first bump of the plurality of first bumps has an elongated shape substantially parallel to an adjacent side of the first region.

According to another aspect of the disclosure, there is provided a semiconductor package including a first substrate, a first pattern and a second pattern disposed on the first substrate, a semiconductor chip disposed on the first substrate and including a semiconductor substrate, a device layer, and a metal layer, a circuit structure disposed on the metal layer of the semiconductor chip, and a plurality of first bumps disposed between the first substrate and the semiconductor chip and electrically connected to the first pattern, wherein the semiconductor chip is disposed on the first substrate, such that the metal layer faces the first substrate, the metal layer includes a wiring metal, and the circuit structure is exposed toward the first substrate from the wiring metal, the first pattern includes a ground pattern or a power pattern, the first substrate includes a first region overlapping the circuit structure in a vertical direction, the plurality of first bumps are disposed adjacent to the first region on a top surface of the first substrate, and a first bump of the plurality of first bumps has an elongated shape substantially parallel to an adjacent side of the first region.

According to another aspect of the disclosure, there is provided a semiconductor package including a first substrate, a first pattern and a second pattern disposed on the first substrate, a semiconductor chip disposed on the first substrate and including a semiconductor substrate, a device layer, and a metal layer, a circuit structure disposed on the metal layer, a plurality of first bumps positioned between the first substrate and the semiconductor chip and electrically connected to the first pattern, and a plurality of second bumps located between the first substrate and the semiconductor chip and electrically connected to the second pattern, wherein the semiconductor chip is disposed on the first substrate, such that the metal layer faces the first substrate, the metal layer includes a wiring metal, and the circuit structure is exposed toward the first substrate from the wiring metal, the first pattern includes a ground pattern or a power pattern, and the second pattern includes a ground pattern, a power pattern, or a signal pattern, the first substrate includes a first region overlapping the circuit structure in a vertical direction, a plurality of the first bumps disposed adjacent to sides of the first region on a top surface of the first substrate, and a first bump of the plurality of bumps has a first width and a second width that is greater than the first width in a direction perpendicular to the first width and is disposed on the top surface of the first substrate, such that the second width is substantially parallel to the first region and the plurality of first bumps at least partially surrounding the first region.

### BRIEF DESCRIPTION OF THE DRAWINGS

Embodiments of the disclosure will be more clearly understood from the following detailed description taken in conjunction with the accompanying drawings in which:

FIG. 1 is a schematic cross-sectional view of a semiconductor package according to an embodiment;

FIG. 2 is a schematic plan view of a first substrate of FIG. 1;

FIG. 3 is an enlarged view of a portion AA of FIG. 2;

FIG. 4 is a schematic cross-sectional view of the inside of the first substrate of FIG. 1;

FIG. 5 is schematic cross-sectional view of an embodiment of a semiconductor chip of FIG. 1;

FIG. 6 is schematic cross-sectional view of an embodiment of a semiconductor chip of FIG. 1;

FIG. 7 is a schematic plan view of an embodiment of a first bump of FIG. 1;

FIG. 8 is a schematic plan view of an embodiment of a first bump of FIG. 1; and

FIG. 9 is a schematic plan view of an embodiment of a first bump of FIG. 1.

### DETAILED DESCRIPTION

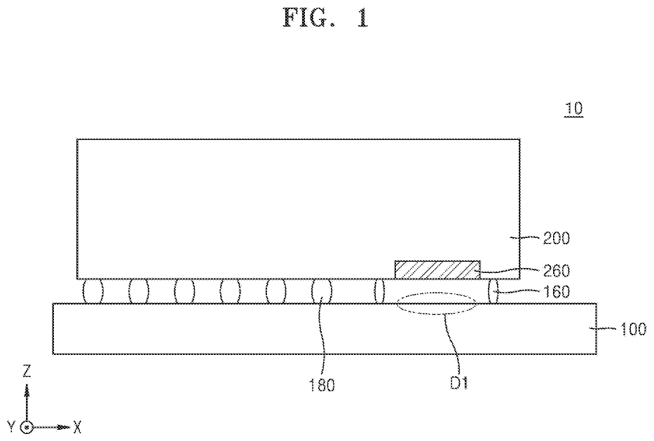

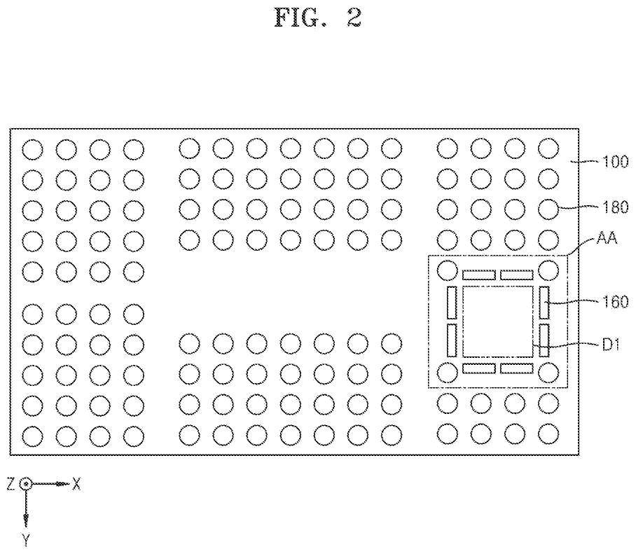

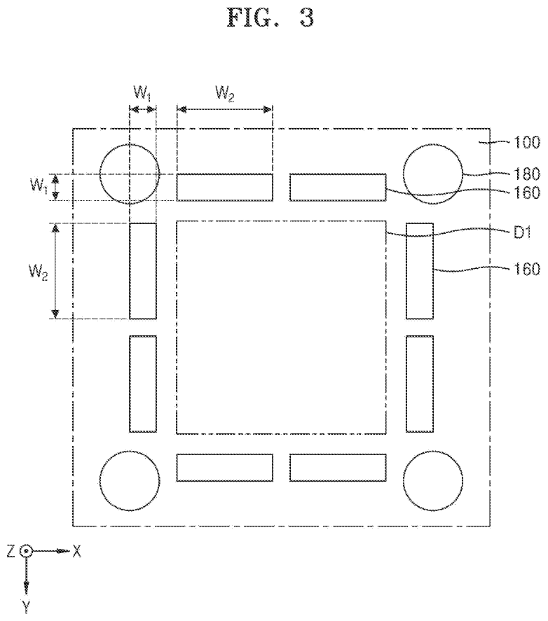

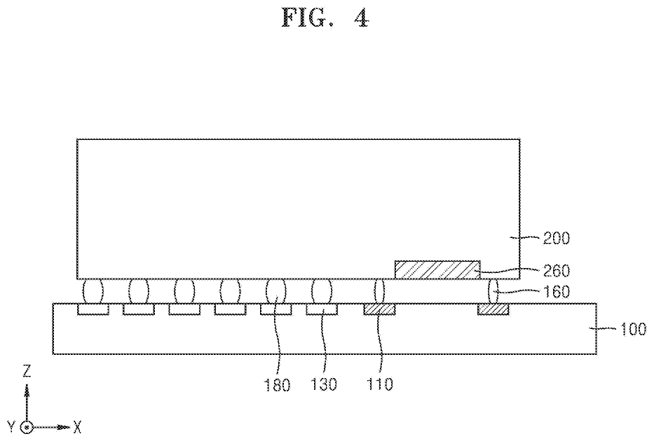

FIG. 1 is a schematic cross-sectional view of a semiconductor package according to an embodiment. FIG. 2 is a schematic plan view of a first substrate of FIG. 1. FIG. 3 is an enlarged view of a portion AA of FIG. 2. FIG. 4 is a schematic cross-sectional view of the inside of the first substrate of FIG. 1.

Referring to FIGS. 1 to 4, a semiconductor package 10 may include a first substrate 100, a plurality of first bumps 160, a plurality of second bumps 180, and a semiconductor chip 200.

The first substrate 100 may be positioned below the semiconductor chip 200. The first substrate 100 may have a top surface and a bottom surface opposite to the top surface. In the drawings, an X-axis direction and a Y-axis direction indicate directions parallel to the top surface or the bottom surface of the first substrate 100, and the X-axis direction and the Y-axis direction may be directions perpendicular to each other. A Z-axis direction may indicate a direction perpendicular to the top surface or the bottom surface of the first substrate 100. In other words, the Z-axis direction may be a direction perpendicular to an X-Y plane. Also, in the drawings, a first horizontal direction, a second horizontal direction, and a vertical direction may be understood as follows; the first horizontal direction may be understood as the X-axis direction, the second horizontal direction may be understood as the Y-axis direction, and the vertical direction may be understood as the Z-axis direction.

The first substrate 100 may be, for example, a ceramic substrate, a printed circuit board (PCB), or an organic substrate. The first substrate 100 may include a body layer and a wiring layer. The body layer may include silicon, ceramic, organic material, glass, epoxy resin, etc., which may depend on the type of the first substrate 100. For example, the first substrate 100 may be a PCB, and the body layer may be based on an epoxy resin.

A plurality of wiring layers may be disposed inside the body layer. Each of the plurality of wiring layers may include a signal pattern, a ground pattern, and a power pattern. The signal pattern may interconnect signal pins, the ground pattern may interconnect ground pins, and the power pattern may interconnect power pins. Here, pins may be portions to which connection terminals, such as solder balls, bumps, or vertical contacts, may be connected. The signal pattern may provide a path through which various signals, e.g., a data signal, may be transmitted/received. The signal pattern may provide a path through which various signals, other than the ground pattern and the power pattern, may be transmitted/received.

Although not shown, the plurality of wiring layers may be electrically connected to one another through vertical contacts arranged in the body layer. According to embodiments, a through via penetrating at least a portion of the body layer may be disposed in the body layer. Here, a vertical contact and a through via may be functionally similar in terms of interconnecting wires of different layers. The vertical contact and the through via may be different from each other in size, shape, material, etc. For example, a through via may have a relatively large size and a relatively complex structure as compared to a vertical contact.

The semiconductor chip 200 may be disposed on the first substrate 100. The semiconductor chip 200 may include a memory chip or a logic chip. In an example where the semiconductor chip 200 includes a memory chip, the memory chip may be, for example, a volatile memory chip like dynamic random access memory (DRAM) or static random access memory (SRAM) or a non-volatile memory chip like phase-change random access memory (PRAM), magneto-resistive random access memory (MRAM), ferroelectric random access memory (FeRAM), or resistive random access memory (RRAM). In an example where the semiconductor chip 200 includes a logic chip, the logic chip may be, for example, a microprocessor like a central processing unit (CPU), a graphics processing unit (GPU), or an application processor (AP), an analog device, or a digital signal processor.

The semiconductor chip 200 may be electrically connected to the first substrate 100. The semiconductor chip 200 may be electrically connected to the first substrate 100 through the first bumps 160 and the second bumps 180. The semiconductor chip 200 may be mounted on the first substrate 100. According to embodiments, the semiconductor chip 200 may be mounted on the first substrate 100 through the first bumps 160 and the second bumps 180 in a flip chip manner. According to some embodiments, an underfill material layer surrounding the first bumps 160 and the second bumps 180 may be disposed between the semiconductor chip 200 and the first substrate 100. The underfill material layer may include, for example, an epoxy resin formed by using a capillary under-fill method. According to some embodiments, a molding member may directly fill a gap between the semiconductor chip 200 and the first substrate 100 through a molded under-fill process. In this case, the underfill material layer may be omitted.

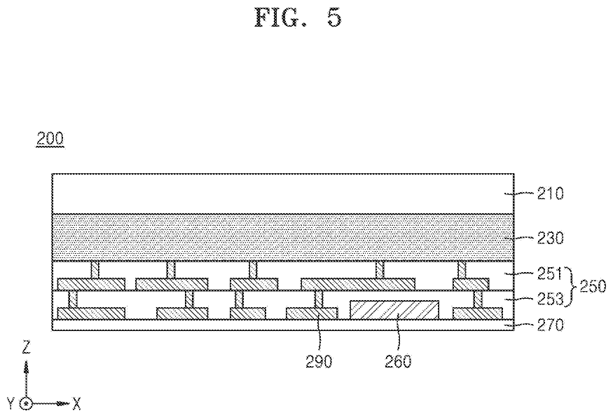

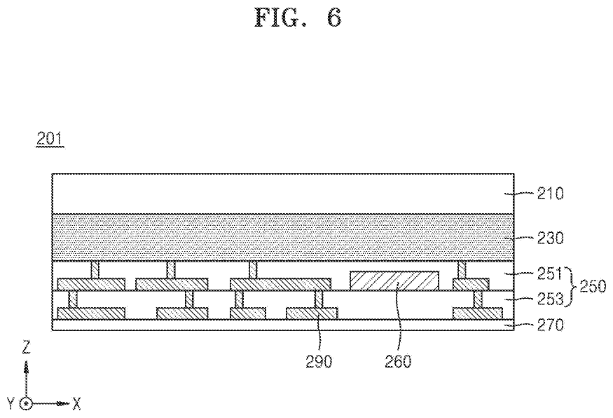

The semiconductor chip 200 may include a circuit structure 260. The circuit structure 260 may be disposed on a chip surface. For example, the circuit structure 260 may be disposed on the bottom surface of the semiconductor chip 200, which may be a surface of the semiconductor chip 200 facing the first substrate 100. The circuit structure 260 may be exposed to the outside of the semiconductor chip 200. The circuit structure 260 may be, for example, an inductor-capacitor phase-locked loop (LC-PLL) circuit. The circuit structure 260 may include an inductor implemented by a circuit and a capacitor. In a case where the circuit structure 260 is exposed to the outside, noise coupling may occur in the circuit structure 260 due to noise generated from a signal pattern, etc. The circuit structure 260 and the semiconductor chip 200 are described herein with reference to FIG. 5 and FIG. 6.

As shown in FIG. 2, the first bumps 160 and the second bumps 180 may be arranged on the top surface of the first substrate 100. A plurality of first bumps 160 and a plurality of second bumps 180 may be provided. According to embodiments, the first bumps 160 and the second bumps 180 may each be connected to patterns disposed on the first substrate 100. A plurality of patterns may be disposed on the first substrate 100. The plurality of patterns may include a signal pattern, a ground pattern, or a power pattern. For example, a first bump 160 may be connected to a ground pattern or a power pattern, and a second bump 180 may be connected to a signal pattern, a ground pattern, or a power pattern. In an embodiment, the first bump 160 may not be connected to a signal pattern.

Referring to FIG. 4 for more detail, a first pattern 110 and a second pattern 130 may be arranged on the top surface of the first substrate 100. The first pattern 110 may include a ground pattern or a power pattern. For example, the first pattern 110 may include a ground pattern or a power pattern. The second pattern 130 may include a signal pattern, a ground pattern, or a power pattern. For example, the second pattern 130 may include a signal pattern, a ground pattern, or a power pattern. In an embodiment, the first bump 160 may not be connected to a signal pattern disposed on the first substrate 100, and the second bump 180 may be connected to a signal pattern, a ground pattern, or a power pattern.

As shown in FIG. 2 and FIG. 3, the plurality of first bumps 160 may be provided, and the plurality of first bumps 160 may be arranged to surround a first region D1. The first region D1 may be a region overlapping the circuit structure 260 of the semiconductor chip 200 in the vertical direction Z on the top surface of the first substrate 100. In other words, the first region D1 may be a region facing the circuit structure 260 on the first substrate 100. The first bump 160 and the second bump 180 may not be formed in the first region D1 of the first substrate 100. An empty space where the first bump 160 and the second bump 180 are not formed may be disposed at the first region D1 of the first substrate 100. According to embodiments, the shape of the first region D1 may be rectangular but is not limited thereto.

The first pattern 110, i.e., a ground pattern or a power pattern, may be disposed in a region of the top surface of the first substrate 100 contacting the first bump 160. A signal pattern may be disposed in a region outside the region of the top surface of the first substrate 100 contacting the first bump 160. The signal pattern may not be disposed in the region of the top surface of the first substrate 100 contacting the first bump 160.

According to embodiments, the cross-sectional shape of the first bump 160 along the XY plane may be a shape elongated in a direction. For example, the cross-sectional shape may be a shape elongated in a direction like a rectangular shape or an elliptical shape. The first bump 160 may have a first width W₁ and a second width W₂. The first width W₁ and the second width W₂ may be understood as widths perpendicular to each other in the cross-sectional shape of the first bump 160 along the XY plane. The second width W₂ may be greater than the first width W₁. For example, when the cross-sectional shape of the first bump 160 is a rectangle, the first width W₁ may be the length of a short side of the rectangle and the second width W₂ may be the length of a long side of the rectangle.

In other words, the first bump 160 may have a shape in which the cross-sectional shape along the XY plane is elongated in a direction. The width of the long side of the cross-sectional shape may refer to the second width W₂ and the width of the short side may refer to the first width W₁.

As described above, the plurality of first bumps 160 may be provided, and the plurality of first bumps 160 may be arranged on the first substrate 100 to surround the first region D1. The first bumps 160 may each be disposed adjacent to the first region D1. The second bump 180 may be disposed at a corner of the first region D1. The second bump 180 may be disposed at a corner of the first region D1 adjacent to a first bump 160 on a first side of the first region D1 and a first bump 180 on a second side of the first region D1. The first side and the second side of the first region D1 may be perpendicular to each other. In other words, the second bump 180 may not be positioned between the first bump 160 and the first region D1.

The first bump 160 may be disposed such that the second width W₂ is substantially parallel to an adjacent side of the first region D1. The first bump 160 may be disposed such that the second width W₂ is parallel to an adjacent side of the first region D1. In other words, the first bump 160 may be disposed such that the second width W₂ faces the first region D1. The first bumps 160 may be arranged having the second width W₂ substantially parallel to an adjacent side of the first region D1, and the first bumps 160 may efficiently surround the first region D1.

The second bump 180 disposed at a corner of the first region D1 may overlap a first bump 160 on a first side of the first region D1 in the X-axis direction and may overlap a first bump on a second side of the first region D1 in the Y-axis direction.

Referring to FIG. 3, the plurality of first bumps 160 may be arranged on the first substrate 100 at least partially surrounding the first region D1. The first bumps 160 arranged on a left side and a right side of the first region D1 may have a shape elongated in the second horizontal direction Y. Therefore, the second width W₂ of the first bumps 160 arranged on the left side and the right side of the first region D1 may refer to the width in the second horizontal direction Y, and the first width W₁ thereof may refer to the width in the first horizontal direction X. Also, each of the first bumps 160 arranged on the left side and the right side of the first region D1 may be disposed such that the second width W₂ is substantially parallel to an adjacent side of the first region D1, that is, the second width W₂ faces the first region D1.

Similarly, in FIG. 3, the first bumps 160 arranged on an upper side and a lower side of the first region D1 may have a shape elongated in the first horizontal direction X. Therefore, the second width W₂ of the first bumps 160 arranged on the upper side and the lower side of the first region D1 may refer to the width in the first horizontal direction X, and the first width W₁ thereof may refer to the width in the second horizontal direction Y. Also, each of the first bumps 160 arranged on the upper side and the lower side of the first region D1 may be disposed such that the second width W₂ is substantially parallel to an adjacent side of the first region D1, that is, the second width W₂ faces the first region D1.

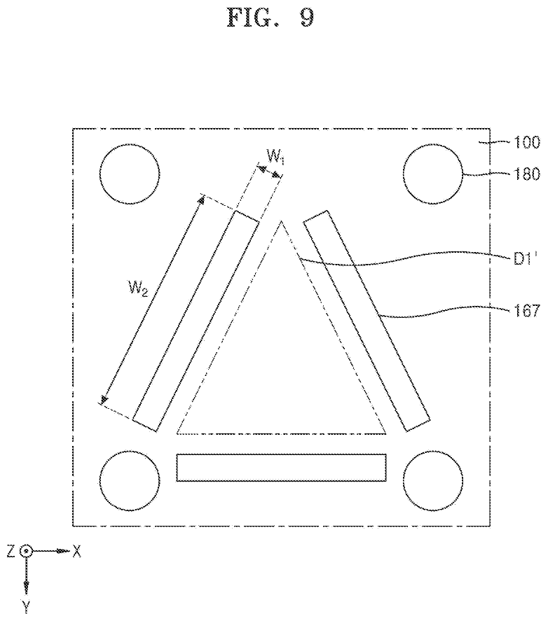

The first bumps 160 arranged on the left side and the right side of the first region D1 and the first bumps 160 arranged on the upper side and the lower side of the first region D1 may be arranged at a certain angle with respect to each other. In FIG. 3, the first bumps 160 arranged on the left side and the right side of the first region D1 and the first bumps 160 arranged on the upper side and the lower side of the first region D1 may be arranged at 90 degrees with respect to each other. The angle is not limited to 90 degrees, and as shown in FIG. 9, the angle may vary according to the shape of the first region D1.

In an example where the first bump 160 has a shape elongated in a direction, side surfaces of the first bump 160 orthogonal to each other may have different cross-sectional areas. For example, the cross-sectional area of the first bump 160 along the YZ plane and the cross-sectional area of the first bump 160 along the XZ plane may be different from each other. The first bump 160 may be disposed such that a side surface having a relatively large cross-sectional area faces the first region D1.

According to some embodiments, the second bump 180 may have a different shape from the first bump 160. For example, the second bump 180 may have a shape like a sphere or a cube. The disclosure is not limited thereto, and the second bump 180 may have the same shape as the first bump 160. As described herein, the second bump 180 may be connected to a signal pattern.

According to some embodiments, the second bump 180 may have a pitch that is different from a pitch of the first bump 160. For example, the second bumps 180 may have a smaller pitch than the first bumps 160. The disclosure is not limited thereto, and the second bumps 180 and the first bumps 160 may have a same pitch.

In the semiconductor package 10 according to embodiments, as the first bumps 160 may be arranged on the first substrate 100 at least partially surrounding the first region D1, and the first bumps 160 may at least partially surround the circuit structure 260. The first bumps 160 may be connected to the first pattern 110 disposed on the first substrate 100, and the first pattern 110 may be a ground pattern or a power pattern. The first bumps 160 may be arranged adjacent to the circuit structure 260 and may transmit a ground signal or a power signal. The first bumps 160 may shield the circuit structure 260 from noise generated from signal patterns, etc. In other words, the first bumps 160 may shield the circuit structure 260 from noise.

The first bumps 160 may each be connected to a ground pattern or a power pattern. In other words, the first bumps 160 may be connected to a same type of pattern. When the first bumps 160 are connected to the same type of pattern, e.g., a ground pattern or a power pattern, the effect of shielding the circuit structure 260 from noise may be further improved. In at least one example, all of the first bumps 160 may be connected to the same type of pattern.

In an example where the first bumps 160 have a shape elongated in a direction and are arranged surrounding the circuit structure 260, the circuit structure 260 of the semiconductor package 10 according to embodiments may be at least partially surrounded by a dense arrangement of the first bumps 160 and effectively shielded from noise.

In an example where the first bumps 160 are connected to the first pattern 110, a signal pattern not included in the first pattern 110 may be disposed outside the first bumps 160. A signal pattern may be disposed far from the circuit structure 260, and noise generated from the signal pattern may have a reduced effect on the circuit structure 260.

FIG. 5 is a schematic cross-sectional view of an embodiment of the semiconductor chip 200 of FIG. 1. Referring to FIG. 5, the semiconductor chip 200 may include a semiconductor substrate 210, a device layer 230, a metal layer 250, and a passivation layer 270.

The semiconductor substrate 210 may have a top surface and a bottom surface that are opposite to each other. The bottom surface of the semiconductor substrate 210 may be a surface facing the first substrate 100 (refer to FIG. 1). The top surface of the semiconductor substrate 210 is opposite to the bottom surface of the semiconductor substrate 210 and may be referred to as an inactive surface, and the bottom surface of the semiconductor substrate 210 may be referred to as an active surface.

The semiconductor substrate 210 may include silicon (Si), e.g., crystalline Si, polycrystalline Si, or amorphous Si. Alternatively, the semiconductor substrate 210 may include a semiconductor element like germanium (Ge) or a compound semiconductor including at least one of silicon carbide (SiC), gallium arsenide (GaAs), indium arsenide (InAs), and indium phosphide (InP). In addition, the semiconductor substrate 210 may have a silicon-on-insulator (SOI) structure.

For example, the semiconductor substrate 210 may include a buried oxide (BOX) layer. The semiconductor substrate 210 may include a conductive region, e.g., a well doped with an impurity or a structure doped with an impurity. The semiconductor substrate 210 may have various device isolation structures like a shallow trench isolation (STI) structure.

The device layer 230 may be disposed on the bottom surface of the semiconductor substrate 210, which may be the active surface. In an example in which the semiconductor chip 200 is mounted on the first substrate 100 in a flip chip manner, the device layer 230 may be positioned below the semiconductor substrate 210, which may be directly on the bottom surface of the semiconductor substrate 210. The semiconductor substrate 210 may be spaced apart from the first substrate 100 in the vertical direction Z with the device layer 230 therebetween.

The metal layer 250 may be positioned under the device layer 230. The device layer 230 may be spaced apart from the first substrate 100 in the vertical direction Z with the metal layer 250 therebetween. The metal layer 250 may include a wiring metal 290. According to embodiments, the metal layer 250 may include a first metal layer 251 and a second metal layer 253. Although FIG. 5 and FIG. 6 show that the metal layer 250 includes the first metal layer 251 and the second metal layer 253, the disclosure is not limited thereto, and the metal layer 250 may include one or more layers. The first metal layer 251 may be disposed directly under the device layer 230, which may be directly on a lower surface of the device layer 230. The second metal layer 253 may be disposed directly under the first metal layer 251, which may be directly on a lower surface of the first metal layer 251.

The first metal layer 251 and the second metal layer 253 may each include the wiring metal 290. The wiring metal 290 may be disposed in the first metal layer 251 and the second metal layer 253. The wiring metal 290 may include copper (Cu), aluminum (Al), titanium (Ti), tungsten (W), etc. As shown in FIG. 5, the circuit structure 260 may be disposed in the second metal layer 253. The circuit structure 260 may be covered by the passivation layer 270. The passivation layer 270 may include Si, aluminum galliumide (AlGaAs), yttrium phosphorus oxide (InGaN), indium phosphorus oxide (InP), indium galliumide (InGaAs), silicon dioxide (SiO2), etc. The passivation layer 270 may cover the wiring metal 290. The passivation layer 270 may be positioned below the wiring metal 290. In an example where the wiring metal 290 is not exposed to the outside due to the passivation layer 270, damage to the wiring metal 290 or oxidation of the wiring metal 290 may be reduced or prevented. The passivation layer 270 may not include a metal.

The circuit structure 260 may be disposed in the second metal layer 253, and no metal may be positioned between the circuit structure 260 and the first substrate 100. In other words, the passivation layer 270, which may not include a metal, may be positioned between the circuit structure 260 and the first substrate 100. In an example in which the passivation layer 270 may not include a metal, and the circuit structure 260 may otherwise be exposed to noise, an arrangement of the first bumps 160 surrounding the circuit structure 260 may be shield the circuit structure 260 from noise (for example, refer to FIG. 3).

FIG. 6 is a schematic cross-sectional view of a semiconductor chip 201 according to an embodiment. According to an embodiment, the semiconductor chip 200 of FIG. 1 may be replaced with the semiconductor chip 201 of FIG. 6. Accordingly, FIG. 6 is a schematic cross-sectional view of an embodiment of the semiconductor chip 200 of FIG. 1. The semiconductor chip 201 shown in FIG. 6 may include the semiconductor substrate 210, the device layer 230, the metal layer 250, and the passivation layer 270. The metal layer 250 may include the first metal layer 251 and the second metal layer 253. The circuit structure 260 may be disposed on the first metal layer 251. When the circuit structure 260 is disposed on the first metal layer 251, the wiring metal 290 disposed on the second metal layer 253 may not overlap the circuit structure 260 in the vertical direction Z. In other words, the circuit structure 260 disposed on the first metal layer 251 may be exposed toward the first substrate 100 from the wiring metal 290 disposed on the second metal layer 253. An insulation layer disposed on the second metal layer 253 and the passivation layer 270 may be positioned between the circuit structure 260 and the first substrate 100. In an example, even when the passivation layer 270 may otherwise expose the circuit structure 260 to noise, an arrangement of the first bumps 160 surrounding the circuit structure 260 may be shield the circuit structure 260 from noise (for example, refer to FIG. 3).

As shown in FIG. 5 and FIG. 6, the circuit structure 260 may be exposed toward the first substrate 100, and the wiring metal 290 may not be covered. In an example, a noise coupling phenomenon on the circuit structure 260 may be reduced or prevented by an arrangement of the first bumps 160 at least partially surrounding the circuit structure 260 (for example, refer to FIG. 3).

In the semiconductor package 10 (refer to FIG. 1) according to embodiments, the first bumps 160 (refer to FIG. 1) may be connected to a ground pattern or a power pattern where the first bumps 160 may be arranged surrounding the circuit structure 260, and the circuit structure 260 may be shielded from noise generated from a signal pattern, etc.

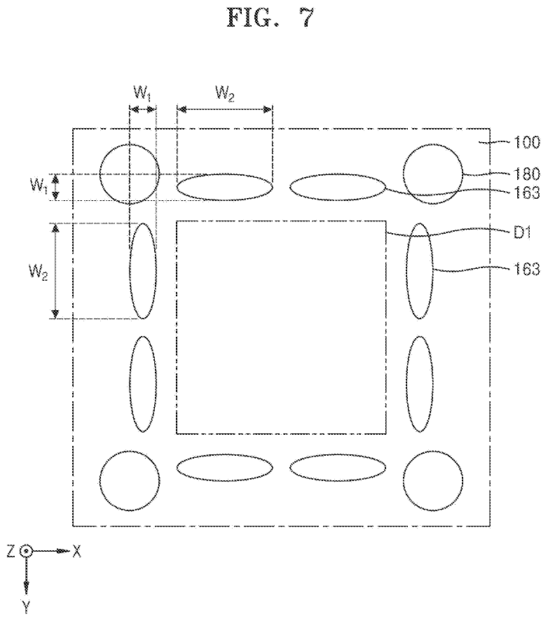

FIG. 7 is a schematic plan view of an embodiment of a first bump of FIG. 1. Hereinafter, repetitive descriptions of the first bumps 160, which have been given herein with reference to FIGS. 1 to 4, may be omitted, and descriptions thereof may focus on the differences between the first bumps 160 and first bumps 163 of FIG. 7.

Referring to FIG. 7, the first bumps 163 and the second bumps 180 may be arranged on the top surface of the first substrate 100. The first bumps 163 may be arranged surrounding the first region D1. The second bumps 180 may not be positioned between the first bumps 163 and the first region D1. The second bump 180 may be disposed at a corner of the first region D1.

The cross-sectional shape of a first bump 163 along the XY plane may be an ellipse. The first width W₁ may be a length of a minor axis of the ellipse and the second width W₂ may be a length of a major axis of the ellipse. According to embodiments, the number of first bumps 163 surrounding the first region D1 may be eight, and two first bumps 163 may be arranged for each side of the first region D1. The number of first bumps 163 is not limited thereto. In FIG. 7, the cross-section of each of the first bumps 163 positioned on the left side and the right side of the first region D1 along the XY plane may have an elongated elliptical shape in the second horizontal direction Y. The length of the major axis of the ellipse extending in the second horizontal direction Y may correspond to the second width W₂ and the length of the minor axis of the ellipse extending in the first horizontal direction X may correspond to the first width W₁.

The cross-section of each of the first bumps 163 positioned on the upper side and the lower side of the first region D1 along the XY plane may have an elongated elliptical shape in the first horizontal direction X. The length of the major axis of the ellipse extending in the first horizontal direction X may correspond to the second width W₂ and the length of the minor axis of the ellipse extending in the second horizontal direction Y may correspond to the first width W₁.

The first bumps 163 surrounding the first region D1 may be arranged, such that their major axes face toward the first region D1 in their cross-sections along the XY plane.

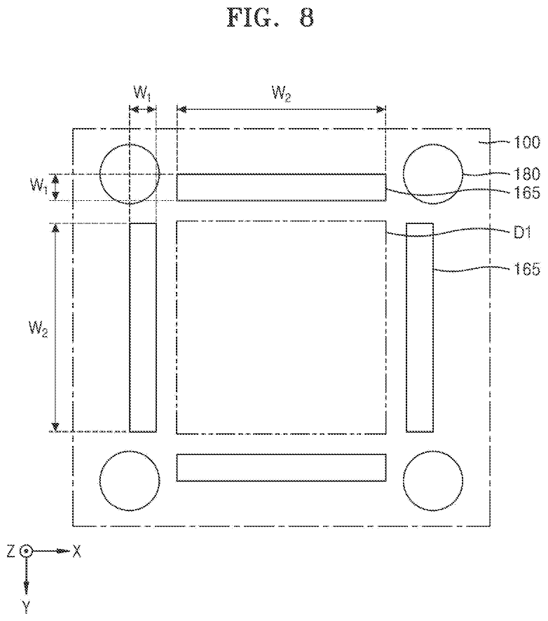

FIG. 8 is a schematic plan view of an embodiment of a first bump of FIG. 1. Hereinafter, repetitive descriptions of the first bumps 160, which have been given herein with reference to FIGS. 1 to 4, may be omitted, and descriptions thereof may focus on the differences between the first bumps 160 and first bumps 165 of FIG. 8.

Referring to FIG. 8, the first bumps 165 and the second bumps 180 may be arranged on the top surface of the first substrate 100. The first bumps 165 may be arranged at least partially surrounding the first region D1. The second bumps 180 may not be positioned between the first bumps 165 and the first region D1. The second bump 180 may be disposed at a corner of the first region D1.

The cross-sectional shape of a first bump 165 along the XY plane may be a rectangle.

However, the disclosure is not limited thereto, and the cross-sectional shape of the first bump 165 along the XY plane may be an ellipse or a polygon as shown in FIG. 7.

According to embodiments, the first region D1 may have a rectangular shape, and four first bumps 165 surrounding the first region D1 may be provided. One first bump 165 may be provided for each side of the first region D1 having a rectangular shape.

When one first bump 165 is provided for each side of the first region D1 having a rectangular shape, the first bumps 165 may form a dense arrangement surrounding the circuit structure 260 (refer to FIG. 1) disposed on the first region D1. In other words, when a plurality of first bumps 165 are provided on each side of the first region D1 having a rectangular shape, an empty space may be formed between the first bumps 165 located on each side, and thus, noise may be introduced into the circuit structure 260 through the empty space. When one first bump 165 is provided on each side of the first region D1 having a rectangular shape, no empty space may be formed, and thus, the circuit structure 260 may be more completely shielded from noise.

FIG. 9 is a schematic plan view of an embodiment of a first bump of FIG. 1. Hereinafter, repetitive descriptions of the first bumps 165, which have been given herein with reference to FIG. 8 may be omitted, and descriptions thereof may focus on the differences between the first bumps 165 and first bumps 167 of FIG. 9.

Referring to FIG. 9, the first bumps 167 and the second bumps 180 may be arranged on the top surface of the first substrate 100. The first bumps 167 may be arranged at least partially surrounding a first region D1′. The second bumps 180 may not be positioned between the first bumps 167 and the first region D1′. The second bump 180 may be disposed at a corner of the first substrate 100.

According to embodiments, the first region D1′ may have a triangular shape. The disclosure is not limited thereto, and, since the first region D1′ is a portion where the circuit structure 260 (refer to FIG. 1) overlaps the first substrate 100 in the vertical direction Z, the shape of the first area D1′ may also vary according to the shape of the circuit structure 260. For example, the first region D1′ may have various shapes like a circle, an ellipse, and a polygon.

The first bumps 167 may be arranged surrounding the first region D1′. A first bump 167 may be disposed at each side of the first region D1 having a triangular shape. However, the disclosure is not limited thereto, and a plurality of first bumps 167 may be arranged for each side of the first region D1′ having a triangular shape. The first bumps 167 may be arranged such that the second width W2 thereof is substantially parallel to an adjacent side of the first region D1′.

For example, in FIG. 9, three first bumps 167 may be arranged at adjacent sides of the first region D1′, and the first bumps 167 may be arranged at an acute angle smaller than about 90 degrees from each other. Also, the first bumps 167 may be arranged such that the second width W2 thereof is substantially parallel to an adjacent side of the first region D1′ having a triangular shape.

At least one of the second bumps 180 may be disposed at a corner of the first region D1′ may overlap a first bump 167 on a first side of the first region D1′ in the X-axis direction and may overlap a first bump on a second side of the first region D1′ in the Y-axis direction. At least another one of the second bumps 180 may be disposed away from a corner of the first region D1′. The at least another one of the second bumps 180 disposed away from a corner of the first region D1′ may not overlap a first bump 167 in at least one of the X-axis direction and the Y-axis direction.

In an example, the first bumps 167 may be arranged on the top surface of the first substrate 100 surrounding the circuit structure 260 regardless of the shape of the circuit structure 260.

While the disclosure has been particularly shown and described with reference to embodiments thereof, it will be understood that various changes in form and details may be made therein without departing from the spirit and scope of the following claims.

What is claimed is:

1. A semiconductor package comprising:
a first substrate;
a first pattern and a second pattern disposed on the first substrate;
a semiconductor chip disposed on the first substrate and comprising a metal layer;
a circuit structure disposed on the metal layer of the semiconductor chip; and
a plurality of first bumps disposed between the first substrate and the semiconductor chip and electrically connected to the first pattern,
wherein the first pattern comprises a ground pattern or a power pattern,
the first substrate includes a first region overlapping the circuit structure in a vertical direction,
the plurality of first bumps are disposed adjacent to the first region on a top surface of the first substrate, and
a first bump of the plurality of first bumps has an elongated shape substantially parallel to an adjacent side of the first region.

2. The semiconductor package of claim 1, wherein the metal layer comprises a wiring metal, and the circuit structure is exposed toward the first substrate from the wiring metal.

3. The semiconductor package of claim 1, wherein the first bump has a first width and a second width that is greater than the first width in a direction perpendicular to the first width, such that a cross-section of the first bump along an XY plane, perpendicular to the vertical direction, has a shape of a rectangle, and
the second width is a length of a long side of the rectangle, and the first width is a length of a short side of the rectangle.

4. The semiconductor package of claim 1, wherein the first bump has a first width and a second width that is greater than the first width in a direction perpendicular to the first width, such that a cross-section of the first bump along an XY plane, perpendicular to the vertical direction, has a shape of an ellipse, and
the second width is a length of a major axis of the ellipse, and the first width is a length of a minor axis of the ellipse.

5. The semiconductor package of claim 1, wherein the semiconductor chip comprises a semiconductor substrate, a device layer disposed on the semiconductor substrate, and a metal layer disposed on the device layer, and
the semiconductor chip is disposed on the first substrate such that the metal layer faces the first substrate.

6. The semiconductor package of claim 1, wherein the plurality of first bumps are arranged at least partially surrounding the first region, wherein second widths thereof face the first region.

7. The semiconductor package of claim 1, wherein the plurality of first bumps are connected to a plurality of first patterns, including the first pattern, respectively, and
the plurality of first patterns are patterns of a same type.

8. The semiconductor package of claim 1, wherein the first region has a polygonal shape, and
at least one first bump of the plurality of first bumps is disposed adjacent to each side of the first region having the polygonal shape.

9. The semiconductor package of claim 1, further comprising a plurality of second bumps connected to the second pattern,
wherein a second bump of the plurality of second bumps has a shape different from that of the first bump.

10. The semiconductor package of claim 9, wherein the second pattern comprises a signal pattern, and the second pattern is spaced apart from the first region in a horizontal direction with the first bump disposed therebetween.

11. The semiconductor package of claim 1, wherein the circuit structure comprises an Inductor-Capacitor Phase-Locked Loop (LC-PLL) circuit.

12. A semiconductor package comprising:
a first substrate;
a first pattern and a second pattern disposed on the first substrate;
a semiconductor chip disposed on the first substrate and comprising a semiconductor substrate, a device layer, and a metal layer;
a circuit structure disposed on the metal layer of the semiconductor chip; and
a plurality of first bumps disposed between the first substrate and the semiconductor chip and electrically connected to the first pattern,
wherein the semiconductor chip is disposed on the first substrate such that the metal layer faces the first substrate,
the metal layer comprises a wiring metal, and the circuit structure is exposed toward the first substrate from the wiring metal,
the first pattern comprises a ground pattern or a power pattern,
the first substrate includes a first region overlapping the circuit structure in a vertical direction,
the plurality of first bumps are disposed adjacent to the first region on a top surface of the first substrate, and
a first bump of the plurality of first bumps has an elongated shape substantially parallel to an adjacent side of the first region.

13. The semiconductor package of claim 12, further comprising a plurality of second bumps connected to a second pattern,
wherein a second bump of the plurality of second bumps has a shape different from that of the first bump, and the second bump is not positioned between the first bump and the first region.

14. The semiconductor package of claim 12, wherein the first bump has a first width and a second width that is greater than the first width in a direction perpendicular to the first width and is disposed on the top surface of the first substrate, and
the plurality of first bumps are arranged at least partially surrounding the first region while the second widths thereof face the first region, and the plurality of first bumps are connected to a plurality of first patterns, including the first pattern, respectively, and
the plurality of first patterns are patterns of a same type.

15. The semiconductor package of claim 12, wherein the first region has a polygonal shape, and
at least one first bump of the plurality of first bumps is disposed adjacent to each side of the first region having the polygonal shape.

16. The semiconductor package of claim 12, wherein the first bump has a first width and a second width that is greater than the first width in a direction perpendicular to the first width and is disposed on the top surface of the first substrate and a cross-section of the first bump along an XY plane, perpendicular to the vertical direction, has a shape of a rectangle, and
the second width is a length of a long side of the rectangle, and the first width is a length of a short side of the rectangle.

17. The semiconductor package of claim 12, wherein the circuit structure comprises an Inductor-Capacitor Phase-Locked Loop (LC-PLL) circuit.

18. A semiconductor package comprising:
a first substrate;
a first pattern and a second pattern disposed on the first substrate;
a semiconductor chip disposed on the first substrate and comprising a semiconductor substrate, a device layer, and a metal layer;
a circuit structure disposed on the metal layer;
a plurality of first bumps positioned between the first substrate and the semiconductor chip and electrically connected to the first pattern; and
a plurality of second bumps located between the first substrate and the semiconductor chip and electrically connected to the second pattern,
wherein the semiconductor chip is disposed on the first substrate such that the metal layer faces the first substrate,
the metal layer comprises a wiring metal, and the circuit structure is exposed toward the first substrate from the wiring metal,
the first pattern comprises a ground pattern or a power pattern, and the second pattern comprises a ground pattern, a power pattern, or a signal pattern,
the first substrate includes a first region overlapping the circuit structure in a vertical direction,
the plurality of first bumps are disposed adjacent to sides of the first region on a top surface of the first substrate, and
a first bump of the plurality of first bumps has a first width and a second width that is greater than the first width in a direction perpendicular to the first width and is disposed on the top surface of the first substrate such that the second width is substantially parallel to the first region and the plurality of first bumps at least partially surrounding the first region.

19. The semiconductor package of claim 18, wherein the first region has a polygonal shape, and
at least one first bump of the plurality of first bumps is disposed adjacent to each side of the first region having the polygonal shape.

20. The semiconductor package of claim 18, wherein the plurality of first bumps have different shapes and pitches than the plurality of second bumps,
a cross-section of the first bump along an XY plane, perpendicular to the vertical direction, has a shape of a rectangle, and
the second width is a length of a long side of the rectangle, and the first width is a length of a short side of the rectangle.
